(19) United States
(12) Patent Application Publication
(10) Pub. No.: US 2023/0085288 A1
(43) Pub. Date: Mar. 16, 2023

(54) ELECTRICALLY INSULATED PROJECTION LINER FOR AI DEVICE

(71) Applicant: INTERNATIONAL BUSINESS MACHINES CORPORATION, Armonk, NY (US)

(72) Inventors: Injo Ok, Loudonville, NY (US); Timothy Mathew Philip, Albany, NY (US); Kevin W. Brew, Niskayuna, NY (US); Muthumanickam Sankarapandian, Niskayuna, NY (US); Steven Michael McDermott, Wynantskill, NY (US); Nicole Saulnier, Slingerlands, NY (US); Andrew Herbert Simon, Fishkill, NY (US); Sanjay C. Mehta, Niskayuna, NY (US)

(21) Appl. No.: 17/472,858

(22) Filed: Sep. 13, 2021

(51) Int. Cl. H01L 45/00

(52) U.S. Cl. CPC H01L 45/126; H01L 45/06; H01L 45/144; H01L 45/16

(57) ABSTRACT

A semiconductor structure includes a heater located in a first layer of a device, wherein the heater is surrounded by a dielectric, a phase change memory (PCM) liner in direct contact with a top surface of the heater in a second layer of the device, a spacer disposed adjacent the PCM liner in the second layer of the device, and a PCM stack disposed above the PCM liner in the second layer of the device.

### BACKGROUND

The present invention relates generally to semiconductor devices, and more specifically, to forming an electrically insulated projection liner for an artificial intelligence (AI) device.

Utilizing phase change memory for analog computing requires memory cells with resistance that changes linearly with programming pulses and is predictable and repeatable. Amorphous phase change materials often suffer from “resistance drift,” whereby the resistance of the cell changes over time, which makes the resistance of the cell unpredictable.

### SUMMARY

In accordance with an embodiment, a semiconductor structure is provided. The semiconductor structure includes a heater located in a first layer of a device, wherein the heater is surrounded by a dielectric, a phase change memory (PCM) liner in direct contact with a top surface of the heater in a second layer of the device, a spacer disposed adjacent the PCM liner in the second layer of the device, and a PCM stack disposed above the PCM liner in the second layer of the device.

In accordance with another embodiment, a semiconductor structure is provided. The semiconductor structure includes a heater positioned within a dielectric, wherein the heater defines projection segments on opposed ends thereof and a PCM stack disposed in direct contact with the heater and the projection segments of the heater.

In accordance with yet another embodiment, a method is provided. The method includes forming a heater in a first layer of a device, wherein the heater is surrounded by a dielectric, depositing a phase change memory (PCM) liner in direct contact with a top surface of the heater in a second layer of the device, forming a spacer adjacent the PCM liner in the second layer of the device, and depositing a PCM stack above the PCM liner in the second layer of the device.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a plurality of conductive lines formed within a dielectric layer and where metal deposition takes place over one or more of the plurality of conductive lines, in accordance with an embodiment of the present invention;

FIG. 2 is a cross-sectional view of the semiconductor structure of FIG. 1 where a liner is deposited, in accordance with an embodiment of the present invention;

FIG. 3 is a cross-sectional view of the semiconductor structure of FIG. 2 where the liner is patterned to form liner sections over one or more of the conductive lines, in accordance with an embodiment of the present invention;

FIG. 4 is a cross-sectional view of the semiconductor structure of FIG. 3 where spacers are formed adjacent the liner sections, in accordance with an embodiment of the present invention;

FIG. 5 is a cross-sectional view of the semiconductor structure of FIG. 4 where GeSbTe (germanium-antimony-tellurium or GST) patterning takes place, in accordance with an embodiment of the present invention;

FIG. 6 is a cross-sectional view of the semiconductor structure of FIG. 5 where top metal formation takes place, in accordance with an embodiment of the present invention;

FIG. 7 is a cross-sectional view of the semiconductor structure including a plurality of conductive lines formed within a dielectric layer and where organic planarization layer (OPL) patterning takes place, in accordance with another embodiment of the present invention;

FIG. 8 is a cross-sectional view of the semiconductor structure of FIG. 7 where the hardmask layers are etched to expose another dielectric layer formed over the conductive lines, in accordance with an embodiment of the present invention;

FIG. 9 is a cross-sectional view of the semiconductor structure of FIG. 8 where a lithography stack is deposited and openings are created to a top surface of one or more of the conductive lines, in accordance with an embodiment of the present invention;

FIG. 10 is a cross-sectional view of the semiconductor structure of FIG. 9 where the lithography stack is removed, in accordance with an embodiment of the present invention;

FIG. 11 is a cross-sectional view of the semiconductor structure of FIG. 10 where the dielectric layer formed over the conductive lines is selectively etched adjacent a top portion of the created openings, in accordance with an embodiment of the present invention;

FIG. 12 is a cross-sectional view of the semiconductor structure of FIG. 11 where the remaining hardmask portions are removed to completely expose the dielectric layer formed over the conductive lines, in accordance with an embodiment of the present invention;

FIG. 13 is a cross-sectional view of the semiconductor structure of FIG. 12 where metal deposition takes place, in accordance with an embodiment of the present invention;

FIG. 14 is a cross-sectional view of the semiconductor structure of FIG. 13 where the metal is planarized, in accordance with an embodiment of the present invention;

FIG. 15 is a cross-sectional view of the semiconductor structure of FIG. 14 where the GST is deposited and patterned, and top metal formation takes place, in accordance with an embodiment of the present invention;

FIG. 16 is a cross-sectional view of the semiconductor structure including a plurality of conductive lines formed within a dielectric layer, where metal deposition takes place over one or more of the plurality of conductive lines, and where a silicon nitride (SiN) layer is deposited thereon, in accordance with another embodiment of the present invention;

FIG. 17 is a cross-sectional view of the semiconductor structure of FIG. 16, where the SiN layer is patterned, in accordance with another embodiment of the present invention;

FIG. 18 is a cross-sectional view of the semiconductor structure of FIG. 17, where a liner is deposited, in accordance with another embodiment of the present invention;

FIG. 19 is a cross-sectional view of the semiconductor structure of FIG. 18, where the liner is planarized, in accordance with another embodiment of the present invention; and

FIG. 20 is a cross-sectional view of the semiconductor structure of FIG. 19, where the GST is deposited and patterned, and top metal formation takes place, in accordance with another embodiment of the present invention.

Throughout the drawings, same or similar reference numerals represent the same or similar elements.

### DETAILED DESCRIPTION

Embodiments in accordance with the present invention provide methods and devices for constructing a projection segment for a phase change memory cell. A self-aligned projection segment is constructed above a heater element. Utilizing phase change memory for analog computing requires memory cells with resistance that changes linearly with programming pulses and is predictable and repeatable. Amorphous phase change materials often suffer from “resistance drift,” whereby the resistance of the cell changes over time, which makes the resistance of the cell unpredictable. To mitigate resistance drift, a projection segment, a parallel resistor that bypasses current around the amorphous volume, is added to the cell. Depending on the geometry of the cell and projection segment, however, the cell resistance can become very non-linear.

Embodiments in accordance with the present invention provide methods and devices for alleviating such issues by forming and patterning a bottom liner below a phase change material to act as a projection segment. In the exemplary methods, the dielectric is recessed and a liner is metallized within the recessed shape. Further, in the exemplary methods, the conductive liner is deposited and then patterned to form a desired shape. Moreover, the liner is patterned and then a spacer is formed to electrically insulate the sidewalls of the liner.

Phase change materials are capable of being switched between a first structural state in which the material is in a generally amorphous solid phase, and a second structural state in which the material is in a generally crystalline solid phase in the active region of the cell. The term “amorphous” is used to refer to a relatively less ordered structure, more disordered than a single crystal, which has the detectable characteristics such as higher electrical resistivity than the crystalline phase. The term “crystalline” is used to refer to a relatively more ordered structure, more ordered than in an amorphous structure, which has detectable characteristics such as lower electrical resistivity than the amorphous phase. Other material characteristics affected by the change between amorphous and crystalline phases include atomic order, free electron density and activation energy. The material can be switched into either different solid phases or mixtures of two or more solid phases, providing a gray scale between completely amorphous and completely crystalline states.

The change from the amorphous to the crystalline state is generally a lower current operation, requiring a current that is sufficient to raise the phase change material to a level between a phase transition temperature and a melting temperature. The change from crystalline to amorphous, referred to as “reset,” is generally a higher current operation, which includes a short high current density pulse to melt or break down the crystalline structure, after which the phase change material cools quickly, quenching the phase change process, thus allowing at least a portion of the phase change structure to stabilize in the amorphous state.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

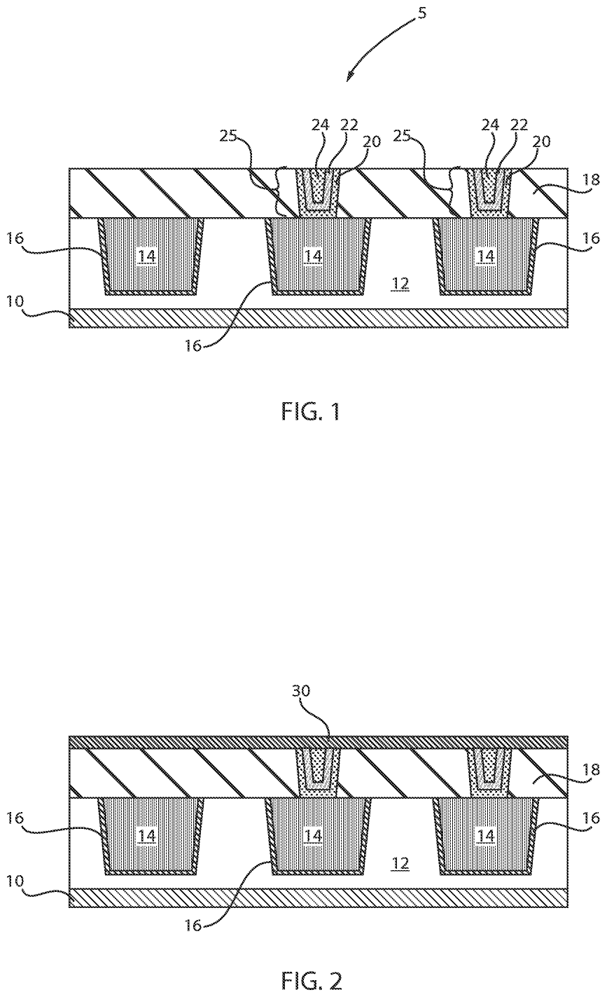

FIG. 1 is a cross-sectional view of a semiconductor structure including a plurality of conductive lines formed within a dielectric layer and where metal deposition takes place over one or more of the plurality of conductive lines, in accordance with an embodiment of the present invention.

A semiconductor structure 5 includes a plurality of conductive lines 14 formed within trenches of an inter-layer dielectric (ILD) 12. The ILD 12 can be formed over a substrate 10. A conductive fill material or liner 16 can be formed or deposited around each of the trenches. In one example, the liner can be a tantalum nitride (TaN) liner 16 or in the alternative a tantalum (Ta) liner 16. In one example embodiment, the conductive fill material 14 can be deposited, for example, by electroplating, electroless plating, chemical vapor deposition (CVD), atomic layer deposition (ALD) and/or physical vapor deposition (PVD).

In various example embodiments, a dielectric 18 is deposited over the plurality of conductive lines 14. The dielectric 18 can have a thickness of, e.g., 50 nm.

Metal deposition can take place to define a heater 25. The heater 25 can include, e.g., three metal layers. A first metal layer 20, a second metal layer 22, and a third metal layer 24. The second metal layer 22 can be formed within the first metal layer 20 and the third metal layer 24 can be formed within the second metal layer 22. Each metal layer 20, 22, 24 can have a substantially U-shaped configuration. The combination of all three layers can be referred to as a heater 25. Each heater 25 directly contacts a top surface of a conductive line 14. Not every conductive line is associated with a heater. The heater 25 is formed within the dielectric 18.

The first metal line 20 can be, e.g., TiN, the second metal line 22 can be, e.g., TaN, and the third metal line 24 can be, e.g., TiN.

The heater 25 is positioned or located within a first layer of a device. Thus, the heater 25 is surrounded by the dielectric 18 within the first layer of the device.

The substrate 10 can be crystalline, semi-crystalline, microcrystalline, or amorphous. The substrate 10 can be essentially (e.g., except for contaminants) a single element (e.g., silicon), primarily (e.g., with doping) of a single element, for example, silicon (Si) or germanium (Ge), or the substrate 10 can include a compound, for example, GaAs, SiC, or SiGe. The substrate 10 can also have multiple material layers. In some embodiments, the substrate 10 includes a semiconductor material including, but not necessarily limited to, silicon (Si), silicon germanium (SiGe), silicon carbide (SiC), Si:C (carbon doped silicon), silicon germanium carbide (SiGeC), carbon doped silicon germanium (SiGe:C), III-V (e.g., GaAs, AlGaAs, InAs, InP, etc.), II-V compound semiconductor (e.g., ZnSe, ZnTe, ZnCdSe, etc.) or other like semiconductor. In addition, multiple layers of the semiconductor materials can be used as the semiconductor material of the substrate 10. In some embodiments, the substrate 10 includes both semiconductor materials and dielectric materials. The semiconductor substrate 10 can also include a layered semiconductor such as, for example, Si/SiGe, a silicon-on-insulator or a SiGe-on-insulator.

The ILD 12 can include any materials known in the art, such as, for example, porous silicates, carbon doped oxides, silicon dioxides, silicon nitrides, silicon oxynitrides, or other dielectric materials. The ILD 12 can be formed using any method known in the art, such as, for example, chemical vapor deposition, plasma enhanced chemical vapor deposition, atomic layer deposition, or physical vapor deposition. The ILD 12 can have a thickness ranging from about 25 nm to about 200 nm.

The dielectric material of layer 12 can include, but is not limited to, ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 4.

The metal lines 14 can be formed in the openings or trenches formed in the ILD 12. The metal lines 14 can be any conductive materials known in the art, such as, for example, copper (Cu), aluminum (Al), or tungsten (W). The metal lines 14 can be fabricated using any technique known in the art, such as, for example, a single or dual damascene technique. In an embodiment, not illustrated, the metal lines 14 can be copper (Cu) and can include a metal liner, where a metal liner can be metals, such as, for example, tantalum nitride and tantalum (TaN/Ta), titanium, titanium nitride, cobalt, ruthenium, and manganese or a combination of these.

The dielectric layer 18 can be a nitride, for example, a silicon nitride (SiN), an oxynitride, for example, silicon oxynitride (SiON), or a combination thereof. In a preferred embodiment, the dielectric layer 18 can be silicon nitride (SiN), for example, Si₃N₄.

FIG. 2 is a cross-sectional view of the semiconductor structure of FIG. 1 where a liner is deposited, in accordance with an embodiment of the present invention.

A liner 30 is deposited. The liner 30 can be referred to as a phase change material (PCM) liner. The liner 30 can be a metal liner. The metal liner 30 can be constructed from metals, such as, for example, tantalum nitride and tantalum (TaN/Ta), titanium, titanium nitride, cobalt, ruthenium, and manganese.

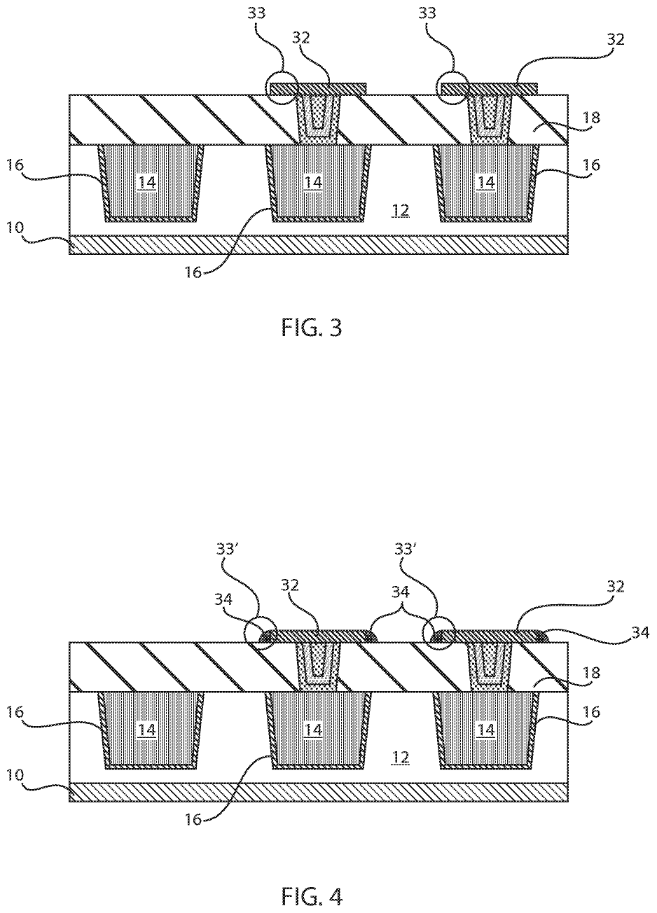

FIG. 3 is a cross-sectional view of the semiconductor structure of FIG. 2 where the liner is patterned to form liner sections over one or more of the conductive lines, in accordance with an embodiment of the present invention.

The liner 30 is patterned to form liner sections or segments 32 directly over the heaters 25. The liner section or segments 32 extends beyond the left and right edges (or distalmost ends) of the top surface of the heater 25. In one example, the liner section 32 has a width equal to the width of the conductive line 14. Thus, the liner section 32 is purposely constructed to be greater than the width of the heater 25. The extended part of the liner sections 32 can be referred to as a projection segment 33. The projection segments 33 on opposed ends of the liner sections 32 can extend to corners of the conductive lines 14.

The liner sections 32 can also be referred to as PCM liner sections 32 or metal liners (ML) 32. The PCM liner sections 32 formed from PCM liner 30 directly contact the top surface of the heater 25 such that the PCM liner and PCM liner sections or PCM projections are within a second layer of the device.

FIG. 4 is a cross-sectional view of the semiconductor structure of FIG. 3 where spacers are formed adjacent the liner sections, in accordance with an embodiment of the present invention.

Spacers 34 are formed adjacent the liner sections 32 within the second layer of the device.

Spacers 34 can include any one or more of SiN, SiBN, SiCN and/or SiBCN films.

The combination of the projection segment 33 and the spacers 34 can define new projection segment 33′. Thus, projection segment 33′ includes the formation of the spacers 34.

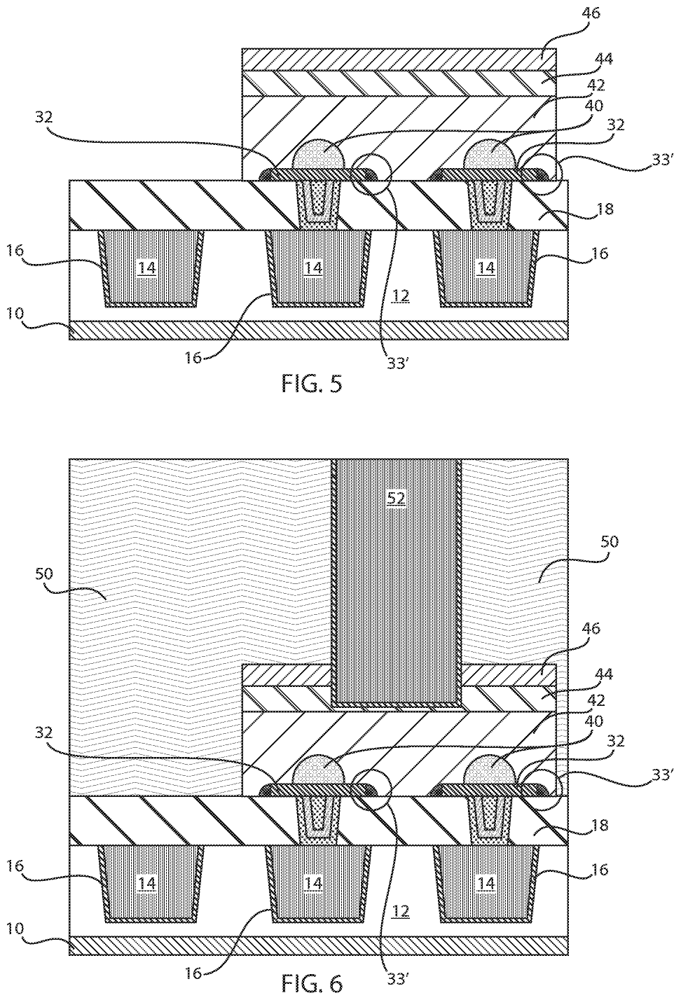

FIG. 5 is a cross-sectional view of the semiconductor structure of FIG. 4 where GeSbTe (germanium-antimony-tellurium or GST) patterning takes place, in accordance with an embodiment of the present invention.

GST patterning takes place. A GST stack can be deposited including amorphous GST dot 40, GST layer 42, TiN layer 44, and SiN layer 46. The amorphous GST dot 40 can be semi-circular in nature. The amorphous GST dot 40 can be vertically aligned with the heater 25. The liner section 32 separates the amorphous GST dot 40 from the heater 25. In one example, the amorphous GST dot 40 can have a width equal to the width of the heater 25. The amorphous GST dot 40 is formed when a voltage is applied to the GST layer 42 and a current goes through the GST layer 42.

FIG. 6 is a cross-sectional view of the semiconductor structure of FIG. 5 where top metal formation takes place, in accordance with an embodiment of the present invention.

An ILD 50 is deposited and a metal contact 52 is formed to the top surface of the TiN layer 44.

The conductive material of the metal contact 52 can be copper (Cu), cobalt (Co), aluminum (Al), platinum (Pt), gold (Au), tungsten (W), titanium (Ti), or any combination thereof. The metal contact 52 can be deposited by a suitable deposition process, for example, chemical vapor deposition (CVD), plasma enhanced chemical vapor deposition (PECVD), physical vapor deposition (PVD), plating, thermal or e-beam evaporation, or sputtering.

Phase change materials can be changed from one phase state to another by application of electrical pulses. A shorter, higher amplitude pulse tends to change the phase change material to a generally amorphous state, and is referred to as a reset pulse. A longer, lower amplitude pulse tends to change the phase change material to a generally crystalline state, and is referred to as a program pulse. The energy in a shorter, higher amplitude pulse is high enough to melt the material in the active volume, and short enough to allow the material to solidify in the amorphous state.

The phase change materials can include chalcogenide based materials and other materials. Chalcogens include any of the four elements oxygen (O), sulfur (S), selenium (Se), and tellurium (Te), forming part of group VI of the periodic table. Chalcogenides include compounds of a chalcogen with a more electropositive element or radical. Chalcogenide alloys include combinations of chalcogenides with other materials such as transition metals. A chalcogenide alloy usually includes one or more elements from column six of the periodic table of elements, such as germanium (Ge) and tin (Sn). Often, chalcogenide alloys include combinations including one or more of antimony (Sb), gallium (Ga), indium (In), and silver (Ag). Phase change based memory materials can include alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable.

Chalcogenides and other phase change materials are doped with impurities in some embodiments to modify conductivity, transition temperature, melting temperature, and other properties of memory elements using the doped chalcogenides. Representative impurities employed for doping chalcogenides include nitrogen, silicon, oxygen, silicon dioxide, silicon nitride, copper, silver, gold, aluminum, aluminum oxide, tantalum, tantalum oxide, tantalum nitride, titanium and titanium oxide.

In the present example, the phase change material stack preferably includes a Ge—Sb—Te (germanium-antimony-tellurium or “GST”) alloy. Alternatively, other suitable materials for the phase change material stack 30 optionally include Si—Sb—Te alloys, Ga—Sb—Te alloys, As—Sb—Te alloys, Ag—In—Sb—Te alloys, Ge—In—Sb—Te alloys, Ge—Sb alloys, Sb—Te alloys, Si—Sb alloys, and combinations thereof.

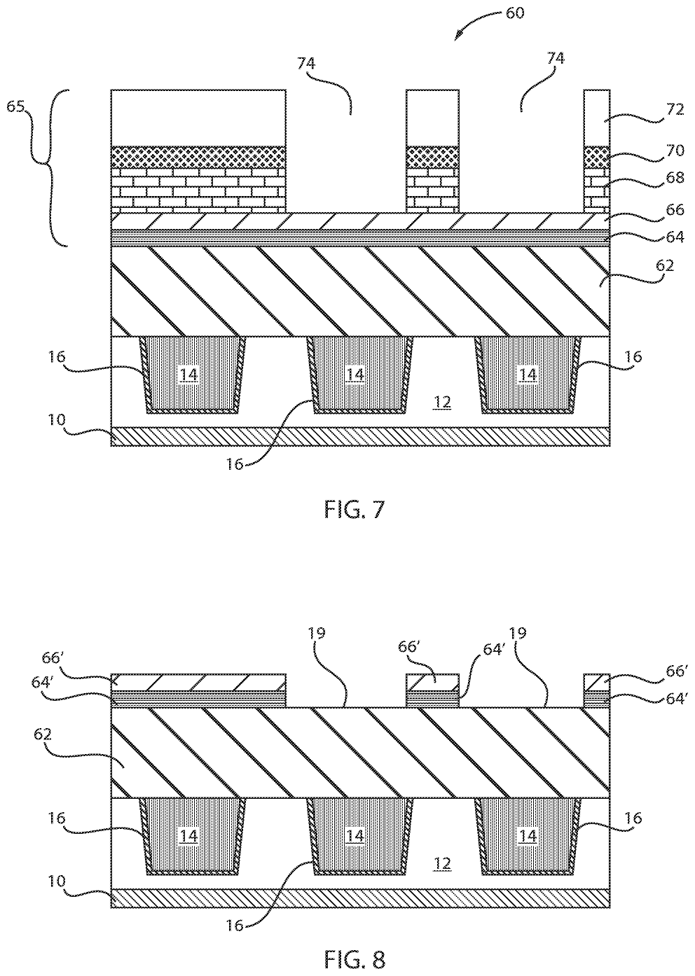

FIG. 7 is a cross-sectional view of the semiconductor structure including a plurality of conductive lines formed within a dielectric layer and where organic planarization layer (OPL) patterning takes place, in accordance with another embodiment of the present invention.

In another embodiment, a lithography stack 65 can be formed over the dielectric layer 62, where the dielectric layer 62 is formed over the conductive lines 14.

The lithographic stack 65 can include a first hardmask layer 64, a second hardmask layer 66, an organic planarization layer (OPL) or organic dielectric layer (ODL) 68, an anti-reflective coating (ARC) layer 70 and a photoresist layer 72.

The lithographic stack 65 can be etched to form openings 74 to a top surface of the hardmask 66.

The first hardmask 64 can be, e.g., TiN and the second hardmask 66 can be, e.g., tetraethyl orthosilicate (TEOS).

The thickness of the OPL 68 can be in a range from about 50 nm to about 300 nm. In one example, the thickness of the OPL 68 is about 200 nm.

The OPL 68 and the ARC layer 70 can be employed as a lithographic stack to pattern the underlying layers. The OPL 68 can be formed at a predetermined thickness to provide reflectivity and topography control during etching of the hard mask layers below. The OPL 68 can include an organic material, such as a polymer.

The layer 70 is an ARC layer which minimizes the light reflection during lithography for a lithography stack. The ARC layer 70 can include silicon, for example, a silicon anti-reflective layer (SiARC). The thickness of the ARC layer 70 can be in range from about 10 nm to about 100 nm. In one example, the thickness of the ARC layer 70 is 35 nm. The anti-reflective film layer 70 can be an antireflective layer for suppressing unintended light reflection during photolithography. Exemplary materials for an antireflective layer include, but are not limited to, metal silicon nitrides, or a polymer film. The anti-reflective layer can be formed, depending on materials, for example, using sputter deposition, chemical vapor deposition, or spin coating.

A photolithography process usually includes applying a layer of photoresist material 72 (e.g., a material that will react when exposed to light), and then selectively exposing portions of the photoresist 72 to light or other ionizing radiation (e.g., ultraviolet, electron beams, X-rays, etc.), thereby changing the solubility of portions of the material. The resist 72 is then developed by washing the resist with a developer solution, such as, e.g., tetramethylammonium hydroxide (TMAH), thereby removing non-irradiated (in a negative resist) or irradiated (in a positive resist) portions of the resist layer. In one example, the thickness of the photoresist 72 is 100 nm.

FIG. 8 is a cross-sectional view of the semiconductor structure of FIG. 7 where the hardmask layers are etched to expose another dielectric layer formed over the conductive lines, in accordance with an embodiment of the present invention.

The lithography stack 65 is reduced such that hardmask layers 64 and 66 only remain. The hardmask layer 64, 66 are further etched such that first hardmask sections 64′ and second hardmask sections 66′ remain. A top surface 19 of the dielectric layer 18 is exposed.

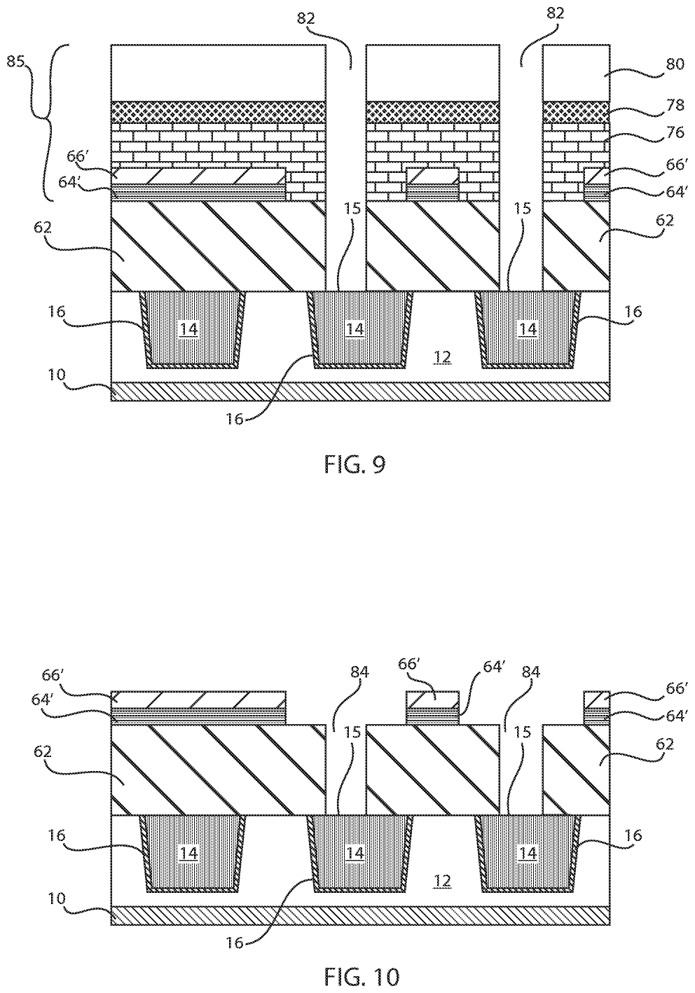

FIG. 9 is a cross-sectional view of the semiconductor structure of FIG. 8 where a lithography stack is deposited and openings are created to a top surface of one or more of the conductive lines, in accordance with an embodiment of the present invention.

A second lithographic stack 85 is deposited.

The second lithographic stack 85 includes an organic planarization layer (OPL) or organic dielectric layer (ODL) 76, an anti-reflective coating (ARC) layer 78 and a photoresist layer 80. The lithographic stack 85 is formed over the first and second hardmask sections 64′, 66′.

The lithographic stack 85 can be etched to form openings 82 to a top surface 15 of the conductive lines 14.

FIG. 10 is a cross-sectional view of the semiconductor structure of FIG. 9 where the lithography stack is removed, in accordance with an embodiment of the present invention.

The second lithographic stack 85 is then removed. The first and second hardmask sections 64′, 66′ are exposed and openings 84 are defined.

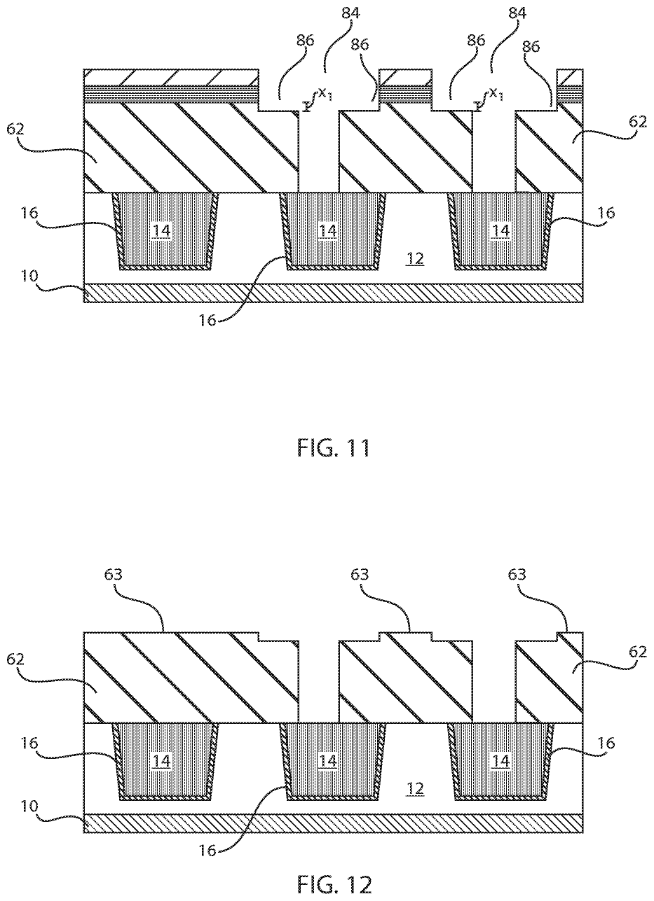

FIG. 11 is a cross-sectional view of the semiconductor structure of FIG. 10 where the dielectric layer formed over the conductive lines is selectively etched adjacent a top portion of the created openings, in accordance with an embodiment of the present invention.

The dielectric layer 18 is selectively etched by an amount or distance xi such that a stepped configuration 86 is defined adjacent the top area of the openings 84. Thus, further selective recessing occurs to the dielectric 18 to create an area or region 86 including a step or indent or depression or notch just below the bottom surface of the first hardmask section 64′.

FIG. 12 is a cross-sectional view of the semiconductor structure of FIG. 11 where the remaining hardmask portions are removed to completely expose the dielectric layer formed over the conductive lines, in accordance with an embodiment of the present invention.

The remaining hardmasks 64′, 66′ are removed to expose a top surface 63 of the dielectric 62.

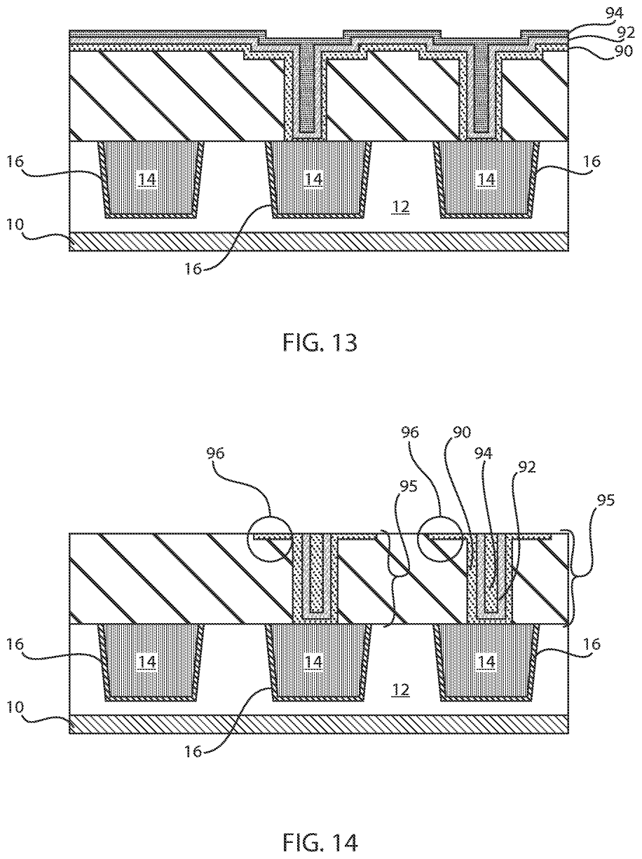

FIG. 13 is a cross-sectional view of the semiconductor structure of FIG. 12 where metal deposition takes place, in accordance with an embodiment of the present invention and FIG. 14 is a cross-sectional view of the semiconductor structure of FIG. 13 where the metal is planarized, in accordance with an embodiment of the present invention.

Metal deposition can take place to define a heater 95 (FIG. 14). The heater 95 can include, e.g., three metal layers. A first metal layer 90, a second metal layer 92, and a third metal layer 94. The second metal layer 92 can be formed within the first metal layer 90 and the third metal layer 94 can be formed within the second metal layer 92. This occurs after planarizing the metals layers 90, 92, 94 (FIG. 14).

The combination of all three layers can be referred to as a heater 95. Each heater 95 directly contacts a top surface of a conductive line 14. Not every conductive line is associated with a heater. The heater 95 is formed within the dielectric 62.

The first metal line 90 can be, e.g., TiN, the second metal line 92 can be, e.g., TaN, and the third metal line 94 can be, e.g., TiN.

The first metal line 90 can have a substantially U-shaped configuration with an extended portion or segment 96 defined on the top surface of the dielectric layer 18. The second metal line 92 can have a substantially U-shaped configuration with no extension or projection. The third metal line 94 is simply a vertical line formed perpendicular to the conductive lines 14.

The segment 96 of the first metal line 90 extends beyond the edges of the conductive line 14. The segment 96 extends along an upper portion of the dielectric 62. The segment 96 in combination with the first, second, and third metal lines 90, 92, 94 defines a substantially T-shaped configuration, where the top portion is narrow and the bottom portion is wide.

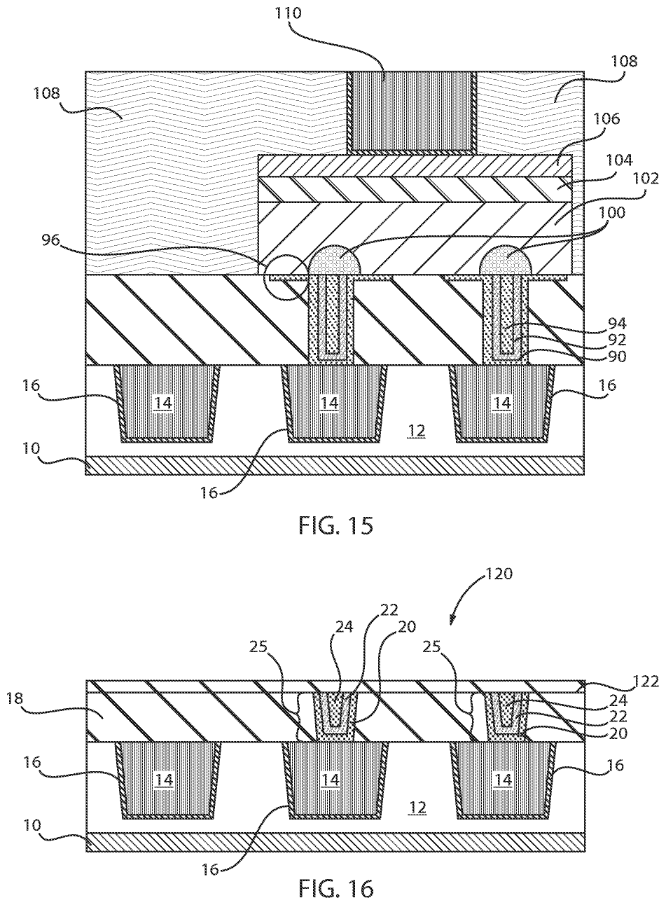

FIG. 15 is a cross-sectional view of the semiconductor structure of FIG. 14 where the GST is deposited and patterned, and top metal formation takes place, in accordance with an embodiment of the present invention.

GST patterning takes place. A GST stack can be deposited including amorphous GST dot 100, GST layer 102, TiN layer 104, and SiN layer 106. An ILD 108 is deposited and a metal contact 110 is formed to the top surface of the TiN layer 106.

The amorphous GST dot 100 can be semi-circular in nature. The amorphous GST dot 100 can be vertically aligned with the heater 95. In one example, the amorphous GST dot 100 can have a width equal to the width of the bottom portion of the heater 95. The amorphous GST dot 100 is formed when a voltage is applied to the GST layer 102 and a current goes through the GST layer 102.

FIG. 16 is a cross-sectional view of the semiconductor structure including a plurality of conductive lines formed within a dielectric layer, where metal deposition takes place over one or more of the plurality of conductive lines, and where a silicon nitride (SiN) layer is deposited thereon, in accordance with another embodiment of the present invention.

A semiconductor structure 120 includes a plurality of conductive lines 14 formed within trenches of an inter-layer dielectric (ILD) 12. The ILD 12 can be formed over a substrate 10. A conductive fill material or liner 16 can be formed or deposited around each of the trenches. In one example, the liner can be a tantalum nitride (TaN) liner 16 or in the alternative a tantalum (Ta) liner 16. In one example embodiment, the conductive fill material 14 can be deposited, for example, by electroplating, electroless plating, chemical vapor deposition (CVD), atomic layer deposition (ALD) and/or physical vapor deposition (PVD).

In various example embodiments, a dielectric 18 is deposited over the plurality of conductive lines 14. The dielectric 18 can have a thickness of, e.g., 50 nm.

Metal deposition can take place to define a heater 25. The heater 25 can include, e.g., three metal layers. A first metal layer 20, a second metal layer 22, and a third metal layer 24. The second metal layer 22 can be formed within the first metal layer 20 and the third metal layer 24 can be formed within the second metal layer 22. Each metal layer 20, 22, 24 can have a substantially U-shaped configuration. The combination of all three layers can be referred to as a heater 25. Each heater 25 directly contacts a top surface of a conductive line 14. Not every conductive line is associated with a heater. The heater 25 is formed within the dielectric 18.

The first metal line 20 can be, e.g., TiN, the second metal line 22 can be, e.g., TaN, and the third metal line 24 can be, e.g., TiN.

Additionally, in contrast to FIG. 1, a SiN layer 122 is deposited over the dielectric layer 18 and the heaters 25. The SiN layer 122 can have a thickness of, e.g., 10-20 nm.

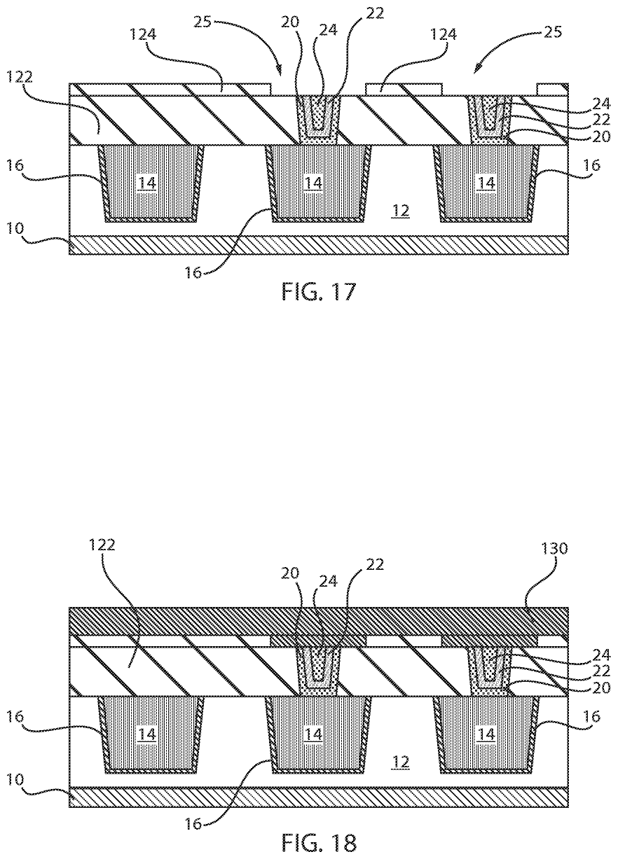

FIG. 17 is a cross-sectional view of the semiconductor structure of FIG. 16, where the SiN layer is patterned, in accordance with another embodiment of the present invention.

The SiN layer 122 is patterned to form SiN layer sections 124. The patterning results in the exposure of the top surface of the heaters 25.

FIG. 18 is a cross-sectional view of the semiconductor structure of FIG. 17, where a liner is deposited, in accordance with another embodiment of the present invention.

A liner 130 is deposited. The liner 130 can be referred to as a phase change material (PCM) liner or metal liner (ML) 130. The liner 130 can be a metal liner. The metal liner 130 can be constructed from metals, such as, for example, tantalum nitride and tantalum (TaN/Ta), titanium, titanium nitride, cobalt, ruthenium, and manganese.

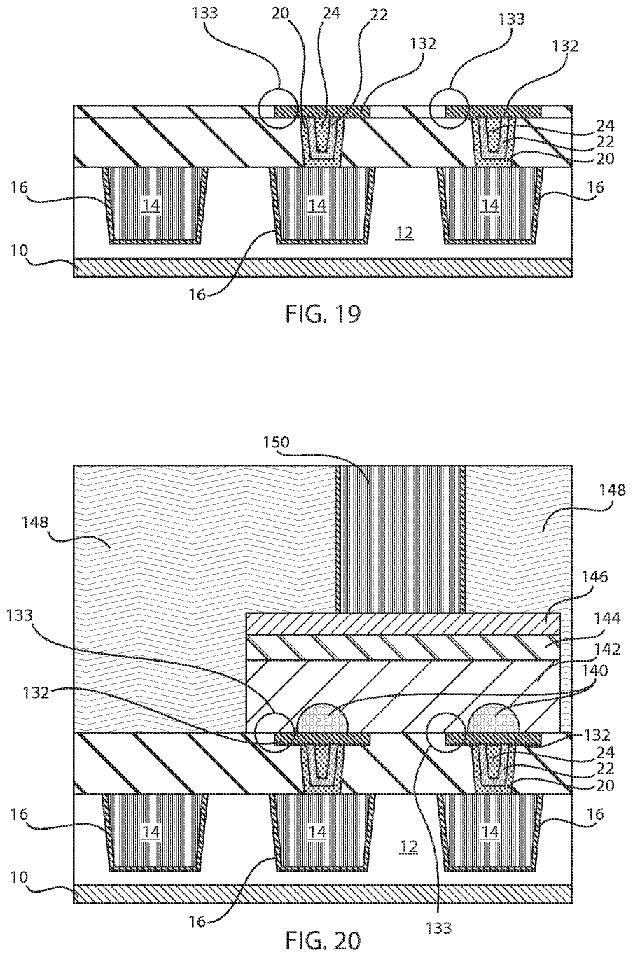

FIG. 19 is a cross-sectional view of the semiconductor structure of FIG. 18, where the liner is planarized, in accordance with another embodiment of the present invention.

The liner 130 is planarized such that liner segments 132 are formed directly over the heaters 25. The liner segments 132 extends beyond the left and right edges of the top surface of the heater 25. In one example, the liner segment 132 has a width equal to the width of the conductive line 14. Thus, the liner segment 132 is purposely constructed to be greater than the width of the heater 25. The extended part of the liner segments 32 can be referred to as a projection segment 133. The projection segments 133 on opposed ends of the liner sections 132 can extend to corners of the conductive lines 14.

FIG. 20 is a cross-sectional view of the semiconductor structure of FIG. 19, where the GST is deposited and patterned, and top metal formation takes place, in accordance with another embodiment of the present invention.

GST patterning takes place. A GST stack can be deposited including amorphous GST dot 140, GST layer 142, TiN layer 144, and SiN layer 146. An ILD 148 is deposited and a metal contact 150 is formed to the top surface of the TiN layer 146.

The amorphous GST dot 140 can be vertically aligned with the heater 25. The heater 25 is separated from the amorphous GST dot 140 by the liner section 132.

In conclusion, the exemplary embodiments of the present invention form a projection segment for a phase change memory cell. The self-aligned projection segment is constructed above the heater element. The PCM structure forms the projection segment with a recessed shape or spacer to protect both sides of the liner.

Regarding FIGS. 1-20, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which include multiple copies of the chip design in question that are to be formed on a wafer. The photolithographic masks are utilized to define areas of the wafer to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys. Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a method for forming an electrically insulated projection liner for an artificial intelligence (AI) device (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a heater located in a first layer of a device, wherein the heater is surrounded by a dielectric;
a phase change memory (PCM) liner in direct contact with a top surface of the heater in a second layer of the device;
a spacer disposed adjacent the PCM liner in the second layer of the device; and
a PCM stack disposed above the PCM liner in the second layer of the device.

2. The semiconductor structure of claim 1, wherein the heater includes three metal layers in a U-shaped configuration.

3. The semiconductor structure of claim 1, wherein the PCM liner extends beyond edges of the top surface of the heater.

4. The semiconductor structure of claim 1, wherein the PCM liner directly contacts portions of a top surface of the dielectric.

5. The semiconductor structure of claim 1, wherein the PCM stack includes a GeSbTe (germanium-antimony-tellurium or GST) layer.

6. The semiconductor structure of claim 5, wherein the GST layer includes amorphous GST.

7. The semiconductor structure of claim 6, wherein the amorphous GST directly contacts the PCM liner.

8. A semiconductor structure comprising:
a heater positioned within a dielectric, wherein the heater defines projection segments on opposed ends thereof; and
a PCM stack disposed in direct contact with the heater and the projection segments of the heater.

9. The semiconductor structure of claim 8, wherein the heater includes three metal layers.

10. The semiconductor structure of claim 9, wherein at least one metal layer of the three metal layers is employed to construct the projection segments.

11. The semiconductor structure of claim 8, wherein the PCM stack includes a GeSbTe (germanium-antimony-tellurium or GST) layer.

12. The semiconductor structure of claim 11, wherein the GST layer includes amorphous GST.

13. The semiconductor structure of claim 12, wherein the amorphous GST directly contacts the heater.

14. The semiconductor structure of claim 11, wherein the PCM stack further includes a titanium nitride (TiN) layer and a silicon nitride (SiN) layer disposed over the GST layer.

15. A method comprising:
forming a heater in a first layer of a device, wherein the heater is surrounded by a dielectric;
depositing a phase change memory (PCM) liner in direct contact with a top surface of the heater in a second layer of the device;
forming a spacer adjacent the PCM liner in the second layer of the device; and
depositing a PCM stack above the PCM liner in the second layer of the device.

16. The method of claim 15, wherein the heater includes three metal layers in a U-shaped configuration.

17. The method of claim 15, wherein the PCM liner extends beyond edges of the top surface of the heater.

18. The method of claim 15, wherein the PCM stack includes a GeSbTe (germanium-antimony-tellurium or GST) layer.

19. The method of claim 18, wherein the GST layer includes amorphous GST.

20. The method of claim 19, wherein the amorphous GST directly contacts the PCM liner.
